(19) United States
(12) Patent Application Publication
(10) Pub. No.: US 2024/0040896 A1
(43) Pub. Date: Feb. 1, 2024

(54) DISPLAY PANEL AND MANUFACTURING THEREOF

(71) Applicant: SHENZHEN CHINA STAR OPTOELECTRONICS SEMICONDUCTOR DISPLAY TECHNOLOGY CO., LTD., Shenzhen (CN)

(72) Inventors: Jingyuan HU, Shenzhen (CN); Xiaoxing ZHANG, Shenzhen (CN)

(21) Appl. No.: 17/622,748

(22) PCT Filed: Dec. 21, 2021
(86) PCT No.: PCT/CN2021/139916

§ 371 Date: Dec. 24, 2021

(30) Foreign Application Priority Data
Dec. 10, 2021 (CN) 202111505619.4

(51) Int. Cl. H10K 59/80; H10K 59/12; H10K 59/123

(52) U.S. Cl. CPC H10K 59/80517; H10K 59/1201; H10K 59/123; H10K 59/87; H10K 2102/101

(57) ABSTRACT

A display panel includes a thin-film transistor, an anode, and a bonding pad. The thin-film transistor includes a source, a drain, and a gate. The anode is electrically connected to the thin-film transistor. A material of the anode includes silver-palladium-copper alloy. The bonding pad is electrically connected to the thin-film transistor. A material of the bonding pad is same as the material of the anode. Since the material of the anode is alloy material formed by adding appropriate proportions of metal elements such as silver, palladium, and copper, which can make an overall material enhance abilities of resisting corrosions of elements such as water vapor, high temperature, sulfide, and oxidation.

### FIELD OF INVENTION

The present invention is related to the field of display technology and specifically to a display panel and a manufacturing method thereof.

### BACKGROUND OF INVENTION

In a display panel of the prior art, since copper (Cu) or copper alloy have good electrical conductivity, the display panel adopts it as metal wirings. The metal wirings, in addition to serving as circuit wirings of the thin-film transistors of the display panel, are also adopted to be electrically connected to a flexible circuit board outside the display panel to achieve an input of external signals. However, since a material of the metal wirings is made of copper or copper alloy materials that easily react with oxygen and water vapor in the air, a part of the metal wirings exposed outside the display panel to be electrically connected to the flexible circuit board is easily oxidized, which affects a bonding effect of the display panel and the flexible circuit board.

In order to solve the above-mentioned technical problems in the prior art, materials having lower activity and corrosion resistance such as molybdenum (Mo) or molybdenum alloys are adopted as a bonding pad, and cover the part of the metal wirings being exposed, to block the metal wirings from reacting with oxygen and water vapor in the air. However, this structural design increases manufacturing processes of the display panel, and increases manufacturing time and manufacturing costs of the display panel.

In addition, an anode of the display panel is made of materials with high reflectivity such as silver (Ag), a composite laminate containing silver, etc. However, similarly, during a manufacturing process of the display panel, since such materials easily react with oxygen and water vapor in the air, or compounds adopted in the manufacturing process, the anode that is temporarily exposed is easily oxidized or sulfurized. When the anode is deteriorated, a disconnection or a short circuit with a cathode of the display panel are likely to occur, causing pixels of the display panel to malfunction, thereby affecting a display effect of the pixels of the display panel.

The display panel of the prior art has technical problems of the metal wirings being easily oxidized, the anode being easily oxidized or sulfurized, and having too many of the manufacturing processes. Therefore, a display panel adopting a corrosion-resistant metal as an anode and a bonding pad is required to solve the above-mentioned technical problems.

### SUMMARY OF INVENTION

An embodiment of the present invention provides a display panel adopting a corrosion-resistant metal as a material of an anode and a bonding pad. The display panel includes a thin-film transistor, the anode, and the bonding pad. The thin-film transistor includes a source, a drain, and a gate. The anode is electrically connected to the thin-film transistor. The material of the anode includes silver-palladium-copper alloy. The bonding pad is electrically connected to the thin-film transistor. The material of the bonding pad is same as the material of the anode.

In an embodiment of the present invention, the anode further includes a transparent conductive oxide disposed on two opposite surfaces of the silver-palladium-copper alloy.

In an embodiment of the present invention, the bonding pad further includes a transparent conductive oxide disposed on two opposite surfaces of the silver-palladium-copper alloy.

In an embodiment of the present invention, the transparent conductive oxide includes indium oxide, antimony oxide, or cadmium oxide.

In this embodiment of the present invention, the display panel further includes a passivation layer. The passivation layer is disposed on the thin-film transistor and covers the thin-film transistor. The passivation layer includes a first through hole defined on the thin-film transistor.

In this embodiment of the present invention, the display panel further includes a planarization layer. The planarization layer is disposed on the passivation layer. The planarization layer includes a second through hole corresponding to the first through hole. The anode is electrically connected to the thin-film transistor through the first through hole and the second through hole.

In this embodiment of the present invention, the first through hole and the second through hole are respectively defined through two manufacturing processes.

In this embodiment of the present invention, the display panel further includes a metal wiring. The metal wiring and the source and the drain of the thin-film transistor are disposed in a same layer. The bonding pad is electrically connected to the thin-film transistor through the metal wiring.

In this embodiment of the present invention, the passivation layer further includes a third through hole defined above the metal wiring. The bonding pad is electrically connected to the metal wiring through the third through hole.

In this embodiment of the present invention, the first through hole and the third through hole are defined through a same manufacturing process.

In an embodiment of the present invention, the thin-film transistor includes a top-gate thin-film transistor.

In an embodiment of the present invention, the display panel is an organic light-emitting diode display panel, and the anode is an anode of an organic light-emitting diode.

An embodiment of the present invention further provides a manufacturing method of a display panel, including:
forming a thin-film transistor and a metal wiring, wherein the thin-film transistor includes a source, a drain, and a gate, and the metal wiring and the source and the drain of the thin-film transistor are formed in a same layer; and
simultaneously forming an anode and a bonding pad electrically connected to the thin-film transistor, wherein a material of the anode includes silver-palladium-copper alloy, and a material of the bonding pad is same as the material of the anode.

In an embodiment of the present invention, the step of simultaneously forming the anode and the bonding pad electrically connected to the thin-film transistor further includes:

sequentially laminating a transparent conductive oxide, a silver-palladium-copper alloy, and a transparent conductive oxide to form the anode and the bonding pad.

In this embodiment of the present invention, the transparent conductive oxide includes indium oxide, antimony oxide, or cadmium oxide.

In an embodiment of the present invention, steps as follows are further included after the step of forming the thin-film transistor:
forming a passivation layer on the thin-film transistor;
forming a planarization layer on the passivation layer;
defining a second through hole on the planarization layer; and
defining a first through hole corresponding to a position of the second through hole on the passivation layer;

The anode is electrically connected to the thin-film transistor through the first through hole and the second through hole.

In this embodiment of the present invention, the step of defining the first through hole corresponding to the position of the second through hole on the passivation layer further includes:

defining a third through hole on the passivation layer simultaneously with the first through.

The bonding pad is electrically connected to the metal wiring through the third through hole.

In an embodiment of the present invention, the thin-film transistor includes a top-gate thin-film transistor.

In an embodiment of the present invention, the display panel is an organic light-emitting diode display panel, and the anode is an anode of an organic light-emitting diode.

The display panel provided by the present invention includes the thin-film transistor, the anode, and the bonding pad. The thin-film transistor includes the source, the drain, and the gate. The anode is electrically connected to the thin-film transistor. The bonding pad is electrically connected to the thin-film transistor. The material of the anode includes a transparent conductive oxide/silver-palladium-copper alloy/transparent conductive oxide laminate. The material of the bonding pad is same as the material of the anode. Since the present invention adopts the transparent conductive oxide/silver-palladium-copper alloy/transparent conductive oxide laminate as the anode and the bonding pad, the present invention can prevent the anode and the bonding pad from a problem of malfunction due to oxidation or sulfurization, and also prevent problems of a disconnection or a short circuit with a cathode of the display panel that can be caused by a deterioration of the anode. In addition, the present invention can also reduce manufacturing processes of the display panel in the prior art, thereby reducing manufacturing time and manufacturing costs of the display panel.

### DESCRIPTION OF DRAWINGS

FIG. 1 is a structural schematic diagram of a display panel of the present invention.

FIGS. 2-7 are structural schematic diagrams of manufacturing processes of the display panel of the present invention.

### DETAILED DESCRIPTION OF EMBODIMENTS

In order to make above purposes, features, and advantages of the present invention more obvious and understandable, the following is a detailed description of preferred embodiments of the present invention in conjunction with accompanying drawings.

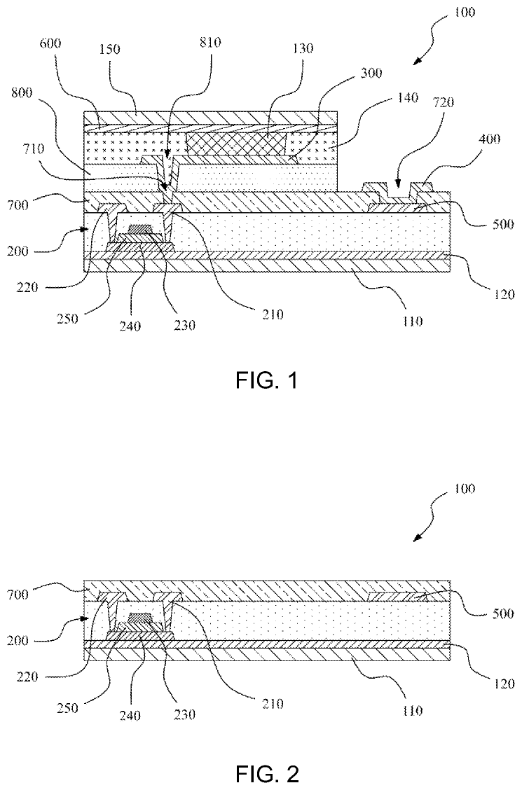

Referring to FIG. 1, which is a structural schematic diagram of a display panel 100 of the present invention. The display panel 100 includes a thin-film transistor 200. The thin-film transistor 200 serves as a driving switch for pixels of the display panel 100 to emit light, and includes a source 210, a drain 220, a gate 230, a channel 240, and a gate insulating layer 250. The thin-film transistor 200 can control on and off of a current on two ends of the source 210 and the drain 220 through controlling an input voltage of the gate 230.

As shown in FIG. 1, the display panel 100 further includes an anode 300, a light-emitting layer 130, and a cathode 600. The light-emitting layer 130 is disposed between the anode 300 and the cathode 600. The anode 300 and the cathode 600 are arranged in a pair. In addition, the anode 300 is electrically connected to one of the source 210 or the drain 220 of the thin-film transistor 200. Therefore, when the thin-film transistor 200 controls the on and off of the current on the two ends of the source 210 and the drain 220, a current or an electric field is generated between the anode 300 and the cathode 600, and the light-emitting layer 130 operates according to the current.

In an embodiment, the display panel 100 further includes a planarization layer 800 and a passivation layer 700. The planarization layer 800 is disposed on the passivation layer 700. The passivation layer 700 includes a first through hole 710 defined on one of the source 210 or the drain 220 of the thin-film transistor 200. The planarization layer 800 includes a second through hole 810 corresponding to the first through hole 710. The anode 300 is electrically connected to one of the source 210 or the drain 220 of the thin-film transistor 200 through the first through hole 710 and the second through hole 810.

In an embodiment, the display panel 100 of the present invention includes an organic light-emitting diode (OLED) display panel. In other words, the anode 300, the light-emitting layer 130, and the cathode 600 together form an organic light-emitting diode. The light-emitting layer 130 further includes a hole injection layer, a hole transport layer, a light-emitting material layer, an electron transport layer, an electron injection layer, etc. When the thin-film transistor 200 controls the current to be conducted to the anode 300, the current is generated between the anode 300 and the cathode 600. Under an action of the current, electrons and holes in the light-emitting layer 130 are combined in the light-emitting material layer and excite light, thereby achieving bright and dark display of the pixels of the display panel 100. It should be noted that the cathode 600 of the present invention includes electrode materials arranged in a piece on an entire surface, so that the cathode 600 can be prepared on the light-emitting layer 130 through an evaporation process, thereby simplifying a structure and manufacturing processes of the display panel 100.

The light-emitting layer 130 of the present invention is not limited to the above-mentioned embodiments. In other embodiments, the light-emitting layer 130 can also include electroluminescent quantum dots (ELQDs), mini-light-emitting diodes (mini-LED), micro-light-emitting diodes (micro-LED), etc.

The display panel 100 being an organic light-emitting diode display panel is taken as an example as follows, and specific embodiments of the present invention are further described.

As shown in FIG. 1, the channel 240 of the thin-film transistor 200 is electrically connected to the source 210 and the drain 220. In an embodiment, the channel 240 is made of a semiconductor material, especially made of indium gallium zinc oxide (IGZO). An electron mobility of the indium gallium zinc oxide adopted in this embodiment is 20-30 times of an electron mobility of a conventional amorphous silicon semiconductor, so a charging and discharging rate and a response speed of the thin-film transistor 200 are significantly enhanced. Adopting the indium gallium zinc oxide as the channel of the thin-film transistor 200 can achieve a faster refresh rate of the display panel 100. In addition, the indium gallium zinc oxide has a better driving capability, so that driving power consumption of the thin-film transistor 200 is low, which makes the display panel 100 more energy-saving and power-saving, and greatly increases a battery life of the display panel 100.

As shown in FIG. 1, in an embodiment, the thin-film transistor 200 includes a top-gate thin-film transistor. In other words, in a structural design of the thin-film transistor 200, the channel 240 is a bottom layer, and the gate is a top layer. The top-gate thin-film transistor can reduce the manufacturing processes of the display panel 100, thereby reducing the manufacturing costs. It should be noted that the thin-film transistor 200 of the present invention is not limited to the top-gate thin-film transistor, and can also be a bottom-gate thin-film transistor or a thin-film transistor of other structure.

In the present invention, a material of the anode 300 includes silver (Ag)-palladium (Pd)-copper (Cu) alloy (APC alloy). Since the material of the anode 300 is an alloy material formed by adding appropriate proportions of silver, palladium, and copper metal elements, it can enhance water vapor resistance, high temperature resistance, sulfurization resistance, and resistance of corrosion of other elements of an overall material.

In an embodiment, the material of the anode 300 further includes a transparent conductive oxide (TCO)/silver-palladium-copper alloy/transparent conductive oxide laminate. Furthermore, the transparent conductive oxide/silver-palladium-copper alloy/transparent conductive oxide laminate is manufactured by continuous deposition of materials through a magnetron sputtering process of a physical vapor deposition (PVD). A method for preparing the transparent conductive oxide/silver-palladium-copper alloy/transparent conductive oxide laminate of the present invention is not limited thereto, and can also be other methods of the physical vapor deposition, even chemical vapor deposition (CVD), etc. In this embodiment, the transparent conductive oxide includes indium oxide, antimony oxide, or cadmium oxide, etc., which are thin film materials that meet characteristics of multi-oxide materials.

As shown in FIG. 1, in an embodiment, the display panel 100 of the present invention further includes a bonding pad 400 and a metal wiring 500. The metal wiring 500 is disposed in a same layer as the source 210 and the drain 220 of the thin-film transistor 200, and is configured to transmit power and signals required by the display panel 100 during an operation, such as Vdd, Vss, etc. The display panel 100 adopts a chip on film (COF) technology to achieve a narrow frame design. Therefore, the metal wiring 500 is electrically connected to the bonding pad 400 in a lateral region of the display panel 100, such that a chip-on-film of a flexible circuit board is bonded to the metal wiring 500.

In this embodiment, the passivation layer 700 further includes a third through hole 720 defined on the metal wiring 500. The bonding pad 40 is electrically connect to the metal wiring 500 through the third through hole 720.

In this embodiment, the bonding pad 400 is electrically connected to one of the source 210, the drain 220, the gate 230 of the thin-film transistor 200, or the cathodes 600 of the display panel 100 through the metal wiring 500. It should be noted that, in actual implementation, the display panel 100 includes a plurality of the thin-film transistors 200, a plurality of the metal wirings 500, and a plurality of the bonding pads 400. Power supply and the signals required for the operation of the display panel 100 are all inputted from the flexible circuit board of the chip on film outside the display panel 100 through each of the bonding pads 400, and are transmitted to the cathode 600 of the display panel 100, the source 210, the drain 220, and the gate 230 of each of the thin-film transistors 200.

In this embodiment, a material of the bonding pad 400 is same as the material of the anode 300. In other words, the material of the bonding pad 400 also includes the silver-palladium-copper alloy. Since the material of the bonding pad 400 is an alloy material formed by adding appropriate proportions of silver, palladium, and copper metal elements, it can enhance water vapor resistance, high temperature resistance, sulfurization resistance, and resistance of corrosion of other elements of the overall material, thereby preventing the metal wiring 500 adopting copper or copper alloy to be directly in contact with the air and be oxidized.

More importantly, in addition to the above technical advantages, since the bonding pad 400 and the anode 300 are configured to be made of a same material, the bonding pad 400 and the anode 300 can be formed in a same manufacturing process. Therefore, compared with the display panel of the prior art having an additional manufacturing process adopting molybdenum (Mo) or molybdenum alloy to make the bonding pads, the present invention can reduce one manufacturing process of the display panel 100 and greatly reduce the manufacturing time and the manufacturing costs of the display panel 100.

After experiments of the inventor, the anode 300 and the bonding pad 400 adopting the transparent conductive oxide/silver-palladium-copper alloy/transparent conductive oxide laminate are performed with a reliability analysis (RA) of a harsh environment at high temperature (60° C.) and high humidity (90 RH), for 500 hours continuously, and still maintain an expected working performance and material properties, and prevent sulfurization, oxidation, and corrosion of other elements.

In addition, the present invention also provides a manufacturing method of a display panel 100. Referring to FIGS. 2-7, which are structural schematic diagrams of manufacturing processes of the display panel 100 of the present invention.

As shown in FIG. 2, in the manufacturing process of the display panel 100, a buffer layer 120 is first formed on a lower glass substrate 110. A channel 240, a gate insulating layer 250, a gate 230, a source 210, and a drain 220 are then sequentially disposed on the buffer layer 120, thus forming a thin-film transistor 200 of the display panel 100.

In an embodiment, a metal wiring 500 and the source 210 and the drain 220 of the thin-film transistor 200 are formed in a same manufacturing process and are electrically connected to one other. The metal wiring 500 is configured to transmit power and signals required by the display panel 100 during an operation.

As shown in FIG. 2, after the source 210, the drain 220, and the metal wiring 500 are formed, a passivation layer 700 is formed thereon. The passivation layer 700 covers the source 210 and the drain 220 of the thin-film transistor 200. The passivation layer 700 not only has an insulating effect, but also provide the display panel 100 with toughness when being flexed, so as to protect the display panel 100.

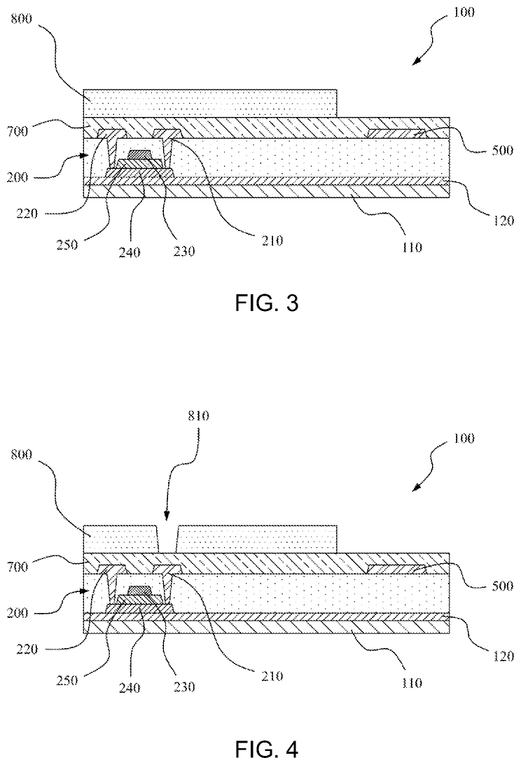

As shown in FIG. 3, in the present invention, a planarization layer 800 is then formed on the passivation layer 700. It should be noted that, when the planarization layer 800 is formed, it does not cover a lateral region of the display panel 100. In order to achieve a narrow frame design, the display panel 100 adopts a chip on film technology. Therefore, the lateral region of the display panel 100 is required to reserve space to provide a flexible circuit board of a chip on film to bond the metal wiring 500.

As shown in FIG. 4, the planarization layer 800 is then patterned. In the present invention, a second through hole 810 is defined in the planarization layer 800 corresponding to one of the source 210 or the drain 220 of the thin-film transistor 200 so as to be exposed in the passivation layer 700 under the second through hole 810.

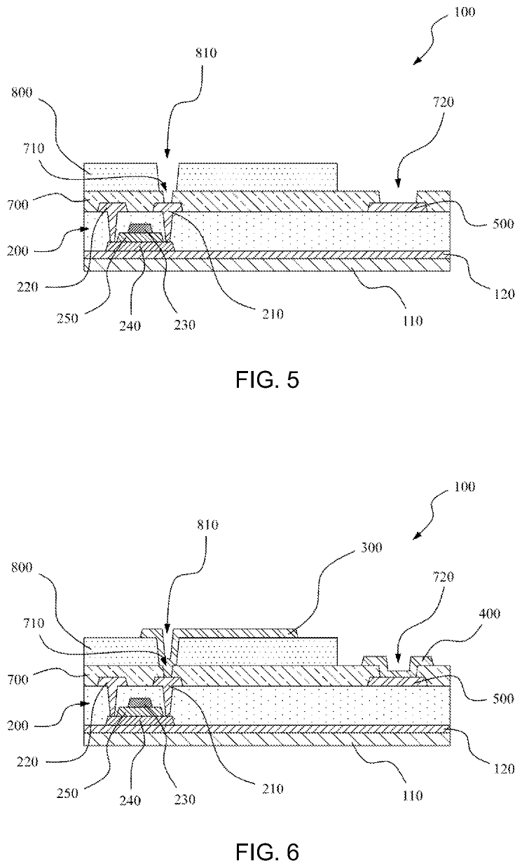

As shown in FIG. 5, the passivation layer 700 is then patterned. In the present invention, a first through hole 710 is defined at a position of the passivation layer 700 corresponding to the second through hole 810 to expose one of the source 210 or the drain 220 of the thin-film transistor 200. At the same time, in the present invention, a third through hole 720 is also defined at a position on the passivation layer 700 corresponding to the metal wiring 500 to expose the metal wiring 500 under the passivation layer 700. In other words, the first through hole 710 and the third through hole 720 are defined through a same manufacturing process. The third through hole 720 is positioned in the lateral region of the display panel 100, i.e., a region where the flexible circuit board of the flip chip film and the metal wiring 500 are bonded.

Since an anode 300 subsequently formed is required to pass through the planarization layer 800 and the passivation layer 700 at one time to be electrically connected to one of the source 210 or the drain 220 of the thin-film transistor 200, the display panel 100 is therefore required to provide through holes penetrating the planarization layer 800 and the passivation layer 700. However, a method for defining through holes in the prior art is as follows: first, after the passivation layer 700 is formed, a temporary through hole that penetrates the passivation layer 700 is defined; and then, the planarization layer 800 is formed on the passivation layer 700, and the temporary through hole is filled; finally, the planarization layer 800 is exposed and developed at one time to define a deep hole penetrating through the temporary through hole and the planarization layer 800 at one time. It is can be understood that a process of defining the deep hole is relatively difficult. When an exposure is incomplete, a material of the planarization layer 800 can remain in the deep hole, causing the deep hole to be incomplete, which easily causes a problem of poor electrical signal transmission to occur in the anode 300 formed subsequently.

In this embodiment, the first through hole 710 and the second through hole 810 are respectively defined through two processes. The second through hole 810 is first defined on the planarization layer 800, and then the first through hole 710 is defined on the passivation layer 700 corresponding to the second through hole 810, which can prevent a problem the prior art that the material of the planarization layer 800 remains in the second through hole 810 and the first through hole 710 due to the deep hole being defined in the planarization layer 800. Therefore, the present invention can increase a yield of an electrical connection between the anode 300 and one of the source 210 or the drain 220 of the thin-film transistor 200.

In addition, the second through hole 810 and the first through hole 710 with overlapping hole positions are successively defined on the planarization layer 800 and the passivation layer 700 one after another, so as to sequentially define the deep hole. After the second through hole 810 is defined on the planarization layer 800, the planarization layer 800 is further undergone through a high-temperature baking process. Since the first through hole 710 is not yet defined on the passivation layer 700, the source 210 and the drain 220 of the thin-film transistor 200 can be protected from oxidation and corrosion of other elements.

As shown in FIG. 6, the anode 300 and the bonding pad 400 are then formed on the planarization layer 800 and the passivation layer 700. The anode 300 is electrically connected to one of the source 210 or the drain 220 of the thin-film transistor 200 through the first through hole 710 and the second through hole 810. In addition, the bonding pad 400 is electrically connected to the metal wiring 500 through the third through hole 720.

In this embodiment, a material of the bonding pad 400 is same as the material of the anode 300. In other words, the material of the bonding pad 400 also includes the silver-palladium-copper alloy. Since the material of the bonding pad 400 is an alloy material formed by adding appropriate proportions of silver, palladium, and copper metal elements, it can enhance water vapor resistance, high temperature resistance, sulfurization resistance, and resistance of corrosion of other elements of the overall material, thereby preventing the metal wiring 500 adopting copper or copper alloy to be directly in contact with the air and be oxidized.

More importantly, in addition to the above technical advantages, since the bonding pad 400 and the anode 300 are configured to be made of a same material, the bonding pad 400 and the anode 300 can be formed in a same manufacturing process. Therefore, compared with the display panel of the prior art having an additional manufacturing process adopting molybdenum or molybdenum alloy to make the bonding pads, the present invention can reduce one manufacturing process of the display panel 100 and greatly reduce the manufacturing time and the manufacturing costs of the display panel 100.

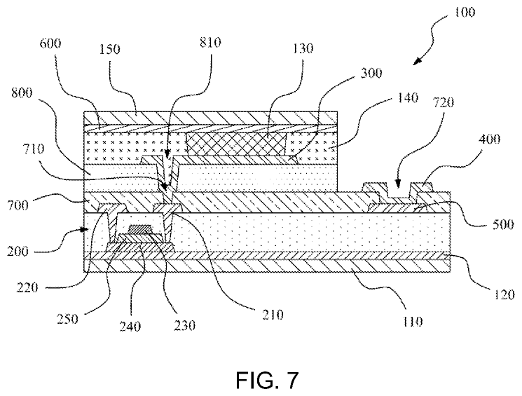

As shown in FIG. 7, after the anode 300 and the bonding pad 400 are formed, in the present invention, a light-emitting layer 130, a pixel defining layer 140, a cathode 600, and an upper glass substrate 150 are then sequentially formed, so as to complete a manufacturing of the display panel 100.

The display panel 100 provided by the present invention includes the thin-film transistor 200, the anode 300, and the bonding pad 400. The thin-film transistor includes the source 210, the drain 220, and the gate 230. The anode 300 is electrically connected to one of the source 210 or the drain 220 of the thin-film transistor 200. The bonding pad 400 is electrically connected to one of the source 210, the drain 220, the gate 230 of the thin-film transistor 200, or the cathode 600 of the display panel 100 of the thin-film transistor 200. The material of the anode 300 includes the transparent conductive oxide/silver-palladium-copper alloy/transparent conductive oxide laminate. The material of the bonding pad 400 is same as the material of the anode 300. Since the present invention adopts the transparent conductive oxide/silver-palladium-copper alloy/transparent conductive oxide laminate as the anode 300 and the bonding pad 400, the present invention can prevent the anode 300 and the bonding pad 400 from a problem of malfunction due to oxidation or sulfurization, and also prevent problems of a disconnection or a short circuit with a cathode 400 of the display panel 100 that can be caused by a deterioration of the anode 300. In addition, the present invention can also reduce manufacturing processes of the display panel in the prior art, and increase the yield of the electrical connection between the anode 300 and one of the source 210 or the drain 220 of the thin-film transistor 200, thereby reducing the manufacturing time and the manufacturing costs of the display panel 100.

The description above are only preferred embodiments of the invention. It should be pointed out that to those of ordinary skill in the art, various improvements and embellishments may be made without departing from the principle of the present invention, and these improvements and embellishments are also deemed to be within the scope of protection of the present invention.

What is claimed is:

1. A display panel, comprising:
a thin-film transistor comprising a source, a drain, and a gate; and
an anode electrically connected to the thin-film transistor, wherein a material of the anode comprises silver-palladium-copper alloy; and
a bonding pad electrically connected to the thin-film transistor, wherein a material of the bonding pad is same as the material of the anode.

2. The display panel according to claim 1, wherein the anode further comprises a transparent conductive oxide disposed on two opposite surfaces of the silver-palladium-copper alloy.

3. The display panel according to claim 2, wherein the transparent conductive oxide comprises indium oxide, antimony oxide, or cadmium oxide.

4. The display panel according to claim 1, wherein the bonding pad further comprises a transparent conductive oxide disposed on two opposite surfaces of the silver-palladium-copper alloy.

5. The display panel according to claim 4, wherein the transparent conductive oxide comprises indium oxide, antimony oxide, or cadmium oxide.

6. The display panel according to claim 1, wherein the display panel further comprises a passivation layer, the passivation layer is disposed on the thin-film transistor and covers the thin-film transistor, and the passivation layer comprises a first through hole defined on the thin-film transistor.

7. The display panel according to claim 6, wherein the display panel further comprises a planarization layer, the planarization layer is disposed on the passivation layer, and the planarization layer comprises a second through hole corresponding to the first through hole; and
the anode is electrically connected to the thin-film transistor through the first through hole and the second through hole.

8. The display panel according to claim 7, wherein the first through hole and the second through hole are respectively defined through two manufacturing processes.

9. The display panel according to claim 7, wherein the display panel further comprises a metal wiring, the metal wiring and the source and the drain of the thin-film transistor are disposed in a same layer, and the bonding pad is electrically connected to the thin-film transistor through the metal wiring.

10. The display panel according to claim 9, wherein the passivation layer further comprises a third through hole defined above the metal wiring, and the bonding pad is electrically connected to the metal wiring through the third through hole.

11. The display panel according to claim 10, wherein the first through hole and the third through hole are defined through a same manufacturing process.

12. The display panel according to claim 1, wherein the thin-film transistor comprises a top-gate thin-film transistor.

13. The display panel according to claim 1, wherein the display panel is an organic light-emitting diode display panel, and the anode is an anode of an organic light-emitting diode.

14. A manufacturing method of a display panel, comprising:
forming a thin-film transistor and a metal wiring, wherein the thin-film transistor comprises a source, a drain, and a gate, and the metal wiring and the source and the drain of the thin-film transistor are formed in a same layer; and
simultaneously forming an anode and a bonding pad electrically connected to the thin-film transistor, wherein a material of the anode comprises silver-palladium-copper alloy, and a material of the bonding pad is same as the material of the anode.

15. The manufacturing method according to claim 14, wherein the step of simultaneously forming the anode and the bonding pad electrically connected to the thin-film transistor further comprises:
sequentially laminating a transparent conductive oxide, a silver-palladium-copper alloy, and a transparent conductive oxide to form the anode and the bonding pad.

16. The manufacturing method according to claim 15, wherein the transparent conductive oxide comprises indium oxide, antimony oxide, or cadmium oxide.

17. The manufacturing method according to claim 14, after the step of forming the thin-film transistor, further comprising:
forming a passivation layer on the thin-film transistor;
forming a planarization layer on the passivation layer;
defining a second through hole on the planarization layer; and
defining a first through hole corresponding to a position of the second through hole on the passivation layer;
wherein the anode is electrically connected to the thin-film transistor through the first through hole and the second through hole.

18. The manufacturing method according to claim 17, wherein the step of defining the first through hole corresponding to the position of the second through hole on the passivation layer further comprises:
defining a third through hole on the passivation layer simultaneously with the first through;
wherein the bonding pad is electrically connected to the metal wiring through the third through hole.

19. The manufacturing method according to claim 14, wherein the thin-film transistor comprises a top-gate thin-film transistor.

20. The manufacturing method according to claim 14, wherein the display panel is an organic light-emitting diode display panel, and the anode is an anode of an organic light-emitting diode.
